(19) United States
(12) Patent Application Publication
(10) Pub. No.: US 2026/0096291 A1
(43) Pub. Date: Apr. 2, 2026

(54) Display Device

(71) Applicant: LG Dislay Co., Ltd., Seoul (KR)

(72) Inventors: Byunggwan Hyun, Paju-si (KR); Seunggyun Kim, Paju-si (KR); Jiyoon Choi, Paju-si (JP)

(21) Appl. No.: 19/280,934

(22) Filed: Jul. 25, 2025

(30) Foreign Application Priority Data
Sep. 27, 2024 (KR) 10-2024-0131831

(51) Int. Cl. H10K 59/122; H10D 86/40; H10D 86/60; H10K 59/35; H10K 59/80; H10K 102/00

(52) U.S. Cl. CPC H10K 59/122; H10D 86/423; H10D 86/60; H10K 59/35; H10K 59/8792; H10K 2102/311

(57) ABSTRACT

A display device includes a substrate including a display area including a plurality of sub-pixels and a non-display area surrounding the display area, a first electrode disposed in each of the sub-pixels on the substrate, a first bank disposed on the first electrode, located at a boundary between adjacent sub-pixels, and including an upper surface and side surfaces, and a second bank that is disposed on the side surface of the first bank and exposes at least a part of the upper surface of the first bank.

### CROSS REFERENCE TO RELATED APPLICATION

The present application claims priority to Republic of Korea Patent Application No. 10-2024-0131831, filed on Sep. 27, 2024, which is hereby incorporated by reference in its entirety.

### BACKGROUND

### Field of Technology

The present specification relates to a display device.

### Description of the Related Art

As the information society develops, various demands for display devices for displaying images are increasing, and various types of display devices such as liquid crystal display (LCD) devices and organic light emitting diode (OLED) display devices are utilized.

A display device includes a plurality of pixels and a plurality of switching elements for driving and controlling the pixels.

### SUMMARY

Embodiments of the present specification are directed to providing a display device in which at least a part of an upper surface of a black bank is exposed to improve reflection of external light.

Embodiments of the present specification are also directed to providing a display device in which a transparent bank is disposed on a side surface of a black bank to form an extra light extraction area around a light-emitting area.

Embodiments of the present specification are also directed to providing a display device in which, since a second bank covers some or all of a side surface of a first bank, it is possible to improve light extraction and implement low power.

Objects of the present specification are not limited to the above-described objects, and other technical objects may be inferred from the following embodiments.

According to one embodiment, there is provided a display device including a substrate including a display area including a plurality of pixels, and a non-display area around the display area, a first electrode disposed in each of the sub-pixels on the substrate, a bank disposed on the first electrode, located at a boundary between adjacent sub-pixels, and including an upper surface and side surfaces, and a second bank that is disposed on the side surfaces of the first bank and exposes at least a part of the upper surface of the first bank According to another embodiment, there is provided a display device including a substrate including a display area including a plurality of pixels, and a non-display area around the display area, a first electrode disposed in each of the sub-pixels on the substrate, a bank disposed on the first electrode, located at a boundary between adjacent sub-pixels, and including an upper surface and side surfaces, and a second bank that is disposed on the side surfaces of the first bank and exposes at least a part of the upper surface of the first bank, wherein the sub-pixel includes a non-light-emitting area corresponding to the first bank, and a light-emitting area exposed by the first bank, and the non-light-emitting area includes an extra light extraction area corresponding to the second bank.

Detailed matters of other embodiments are included in the detailed description and accompanying drawings.

### BRIEF DESCRIPTION OF THE DRAWINGS

FIG. 1 is a plan view of a display device according to one embodiment.

FIG. 2 is a cross-sectional view illustrating a bent state of a display panel according to FIG. 1 according to one embodiment.

FIG. 3 is a cross-sectional view along line A-A′ in FIG. 1 according to one embodiment.

FIG. 4 is a specific cross-sectional view of a light-emitting part of FIG. 3 according to one embodiment.

FIG. 5 is a specific cross-sectional view of a light-emitting part according to a modified example according to one embodiment.

FIG. 6 is a cross-sectional view of a touch part according to FIG. 3 according to one embodiment.

FIG. 7 is a cross-sectional view along line B-B′ in FIG. 1 according to one embodiment.

FIG. 8 is a cross-sectional view along line C-C′ in FIG. 1 according to one embodiment.

FIG. 9 is an enlarged cross-sectional view of area Q1 in FIG. 3 according to one embodiment.

FIG. 10 is a plan view of a pixel according to one embodiment.

FIG. 11 is a cross-sectional view of a display device according to another embodiment.

FIG. 12 is a cross-sectional view of a display device according to still another embodiment.

FIG. 13 is a cross-sectional view of a display device according to yet another embodiment.

FIG. 14 is a cross-sectional view of a display device according to yet another embodiment.

FIG. 15 is a cross-sectional view of the display device according to yet another embodiment.

FIG. 16 is a cross-sectional view of the display device according to yet another embodiment.

FIG. 17 is a cross-sectional view of a display device according to yet another embodiment.

FIG. 18 is a perspective view of a display device according to yet another embodiment.

FIG. 19 is a cross-sectional view along line D-D′ in FIG. 18 according to one embodiment.

### DETAILED DESCRIPTION

Hereinafter, embodiments will be described with reference to the accompanying drawings.

The same reference numerals indicate the same components. In addition, in the drawings, thicknesses, proportions, and dimensions of components can be exaggerated for effective description of technical contents. Scales of components shown in the drawings differ from the actual scale for convenience of description, and thus are not limited to the scales shown in the drawings.

In the specification, when a first component (or an area, a layer, a portion, etc.) is described as “on,” “connected,” or “coupled to” a second component, it means that the first component may be directly connected/coupled to the second component or a third component may be disposed therebetween.

The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions may be positioned between two portions. The spatially relative terms “below or beneath,” “lower,” “above,” “upper,” etc. can be used to easily describe the correlation with one element or components and another element or components as shown in the drawings. The spatially relative terms should be understood as the terms including different directions of elements in use or operation in addition to the directions shown in the drawings. For example, in case of turning the element shown in the drawing upside down, an element described as being disposed “below” or “beneath” another element may be disposed “above” another element. Accordingly, the exemplary term “below”may include both downward and upward directions.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

Features of various embodiments of the present specification may be coupled or combined partially or entirely, various technological interworking and driving are made possible, and the embodiments may be implemented independently of each other or implemented together in an associated relationship.

Hereinafter, a display device of the present specification will be described with reference to the accompanying drawings and embodiments as follows.

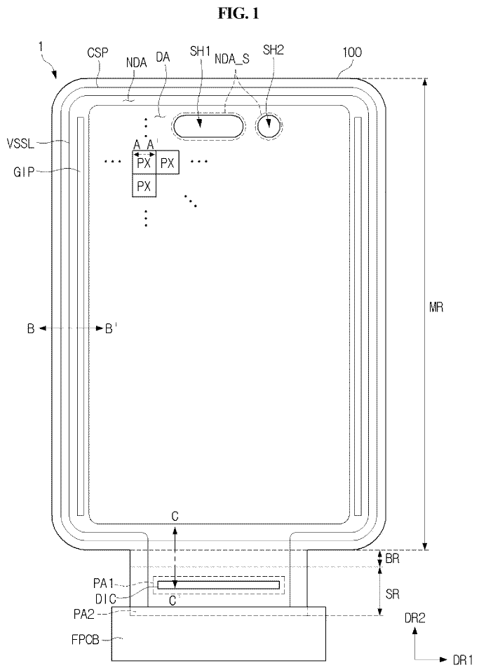

FIG. 1 is a plan view of a display device according to one embodiment.

Referring to FIG. 1, a display device 1 according to one embodiment may include a display panel 100. The display panel 100 may include a display area DA including a plurality of pixels PX and a non-display area NDA around the display area DA. The flat surface shape of the display area DA may have a rectangular shape. However, the embodiments of the present specification are not limited thereto, and the flat surface shape of the display area DA may be a square, circular, elliptical, or other polygonal shapes. For example, the display area DA may have a rectangular shape with rounded corners, but is not limited thereto and may also have a rectangular shape with angled corners.

In embodiments, a first direction DR1 and a second direction DR2 are different directions and intersect each other, for example, directions that intersect vertically in a plan view. In FIG. 1, the first direction DR1 may be generally the same as an extension direction of short sides of the display panel 100, and the second direction DR2 may be the same as an extension direction of long sides of the display panel 100. However, the directions described in the embodiments should be understood as indicating relative directions, and the embodiments are not limited to the described directions.

The display area DA may include short sides extending in the first direction DR1 and long sides extending in the second direction DR2. The non-display area NDA may surround the display area DA. The non-display area NDA may be disposed at one side and the other side of the display area DA in the first direction DR1 and one side and the other side of the display area DA in the second direction DR2.

The display panel 100 may further include a sensor non-display area NDA_S and a sensor hole SH surrounded by the sensor non-display area NDA_S. The sensor hole SH1 and SH2 may be surrounded by the display area DA in a plan view. The sensor hole SH1 and SH2 may be, for example, two sensor holes as in FIG. 1, but the embodiments of the present specification are not limited thereto. For example, the sensor hole may be provided as one sensor hole. The two sensor holes SH1 and SH2 may each include a sensor hole in which an infrared sensor is disposed and a sensor hole in which a camera sensor is disposed, but the embodiments of the present specification are not limited thereto. The sensor non-display area NDA_S may be disposed between the sensor holes SH1 and SH2 and the display area DA. The sensor non-display area NDA_S may completely surround the sensor holes SH1 and SH2. A pixel PX may not be disposed in the sensor non-display area NDA_S.

A gate driving unit GIP (e.g., a circuit) may be disposed in the non-display area NDA located at one side and the other side of the display area DA in the first direction DR1. A low-potential voltage line VSSL may be disposed outside the gate driving unit GIP on the non-display area NDA. For example, as illustrated in FIG. 1, the low-potential voltage line VSSL may extend from a printed circuit board FPCB, pass a sub-region SR and a bending region BR, may be located outside the gate driving unit GIP on the non-display area NDA, and disposed to surround the display area DA.

The non-display area NDA located at the other side of the display area DA in the second direction DR2 may extend further from a central portion of the other side toward the other side of the display area DA in the second direction DR2. A width of the non-display area NDA in the first direction DR1 further extending from the central portion of the other side toward the other side of the display area DA in the second direction DR2 may be smaller than a width of the non-display area NDA in the first direction DR1 adjacent to the other side of the display area DA in the second direction DR2.

A display device 1 may include a main region MR, the sub-region SR, and the bending region BR between the main region MR and the sub-region SR. The display area DA and the non-display area NDA surrounding four surfaces of the display area DA may form the main region MR, and a portion extending from the central portion of the other side toward the other side of the display area DA in the second direction DR2 may form the bending region BR and the sub-region SR. The bending region BR may be disposed between the sub-region SR and the main region MR. The sub-region SR may include a first pad area PA1 and a second pad area PA2 located at an end portion of the other side of the sub-region SR in the second direction DR2. The display device 1 may further include a data driving unit DIC and a printed circuit board FPCB. The data driving unit DIC may be disposed in the first pad area PA1, and the printed circuit board FPCB may be attached to the second pad area PA2. A plurality of pads connected to the data driving unit DIC and the printed circuit board FPCB may be disposed in each of the first pad area PA1 and the second pad area PA2. A plurality of pads connected to the data driving unit DIC and the printed circuit board FPCB may be disposed in each of the first pad area PA1 and the second pad area PA2. The data driving unit DIC (e.g., a circuit) may be configured, for example, in the form of a driving chip (IC), but is not limited thereto. In one embodiment, a case in which the data driving unit DIC is disposed by a chip on plastic method in which the data driving unit DIC is directly mounted on the display panel 100 is described, but the embodiments of the present specification are not limited thereto, and the data driving unit DIC may be disposed by a chip on glass or chip on film method.

The display panel 100 according to one embodiment may further include a crack sensing pattern CSP surrounding the low-potential voltage line VSSL. The crack sensing pattern CSP may be disposed to completely surround the display area DA as illustrated in FIG. 1. For example, the crack sensing pattern CSP may be disposed outside the low-potential voltage line VSSL. However, the embodiments of the present specification are not limited thereto, and a part of the crack sensing pattern CSP may not be disposed in the non-display area NDA of the other side of the display area DA in the second direction DR2.

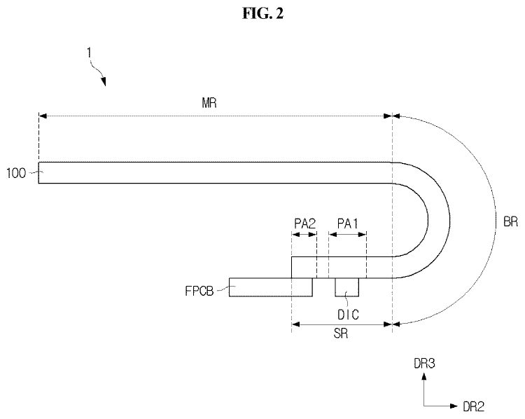

FIG. 2 is a cross-sectional view illustrating a bent state of a display panel according to FIG. 1 according to one embodiment.

Referring to FIG. 2, the bending region BR of the display panel 100 of the display device 1 according to one embodiment may be bent in a thickness direction (or a third direction DR3). Accordingly, the main region MR and the sub-region SR may overlap each other in the thickness direction. The display panel 100 may be bent in such a manner that a lower surface of the main region MR faces an upper surface of the sub-region SR. The printed circuit board FPCB may be attached to an end portion of the sub-region SR.

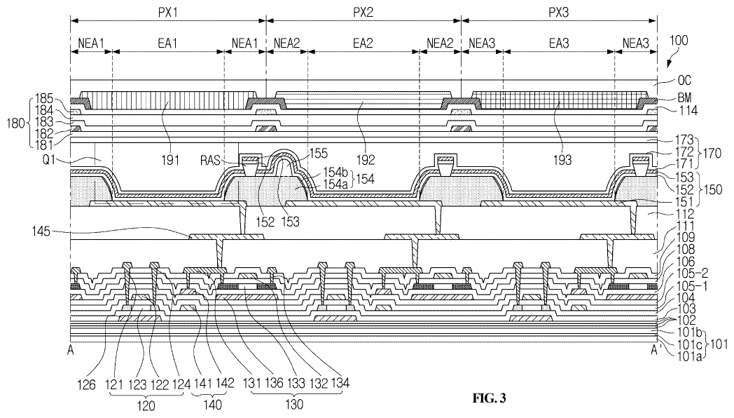

FIG. 3 is a cross-sectional view along line A-A′ in FIG. 1 according to one embodiment.

Referring to FIG. 3, the pixel PX (see FIG. 1) of the display panel 100 may include a plurality of sub-pixels PX1, PX2, and PX3. The first sub-pixel PX1 may be a red sub-pixel, the second sub-pixel PX2 may be a green sub-pixel, and the third sub pixel PX3 may be a blue sub-pixel, but the embodiments of the present specification are not limited thereto. In some embodiments, the pixel PX further includes a fourth sub-pixel, and the fourth sub-pixel may be a white sub-pixel, but the embodiments of the present specification are not limited thereto. In some embodiments, the pixel may include one red sub-pixel, two green sub-pixels, and one blue sub-pixel, but the embodiments of the present specification are not limited thereto. For example, the plurality of sub-pixels PX1, PX2, and PX3 may be arranged in a stripe manner in the first direction DR1, but are not limited thereto, and may be arranged in a pentile manner.

The display panel 100 may include a substrate 101, a first thin film transistor 120, a second thin film transistor 130, a light-emitting part 150, an encapsulation part 170, a touch part 180, a filter insulating layer 114, a black matrix BM, color filters 191, 192, and 193, and a planarization layer OC. The display panel 100 may include at least one panel insulating layer and at least one touch insulating layer between the substrate 101 and the light-emitting part 150. The at least one panel insulating layer may include at least one of a buffer layer 102, a first insulating layer 103, a second insulating layer 104, a 3-1 insulating layer 105-1, a 3-2 insulating layer 105-2, a fourth insulating layer 106, a fifth insulating layer 108, a sixth insulating layer 109, a first protective layer 111, and a second protective layer 112, and the at least one touch insulating layer may include at least one of a touch buffer layer 181, a first touch insulating layer 183, and a second touch insulating layer 184.

The substrate 101 may include one or more plastic materials. For example, the substrate 101 may be a multi-substrate including a plurality of plastic materials, such as polyimide, etc. For example, the substrate 101 may include a first substrate portion 101a and a second substrate portion 101b each including a plastic material, and a third substrate portion 101c including an inorganic insulation material between the first substrate portion 101a and the second substrate portion 101b, but the embodiments of the present specification are not limited thereto.

The buffer layer 102 may be disposed on the substrate 101. The buffer layer 102 can minimize or delay the diffusion of moisture or oxygen penetrating the substrate 101. The buffer layer 102 may be formed by alternately stacking silicon nitride (SiNₓ) and silicon oxide (SiOₓ) at least once, but the embodiments of the present specification are not limited thereto.

A first light-shielding layer 126 may be disposed on the buffer layer 102. The first light-shielding layer 126 can prevent or at least reduce light from transmitting a first semiconductor layer 123 of the first thin film transistor 120. For example, the first semiconductor layer 123 may be disposed to overlap the first light-shielding layer 126. The first light-shielding layer 126 may be formed of a single layer or multiple layers formed of one of molybdenum (Mo), aluminum (Al), chromium (Cr), nickel (Ni), neodymium (Nd), and copper (Cu) or an alloy thereof, but the embodiments of the present specification are not limited thereto.

The first insulating layer 103 may be disposed on the buffer layer 102 and the first light-shielding layer 126. The first insulating layer 103 can prevent a short circuit between a component of the first thin film transistor 120 and the first light-shielding layer 126. The first insulating layer 103 may be formed of the same material as the buffer layer 102, but the embodiments of the present specification are not limited thereto. For example, the first insulating layer 103 may be formed of an inorganic insulation material, such as silicon nitride (SiNₓ) or silicon oxide (SiOₓ), but the embodiments of the present specification are not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, etc., but the embodiments of the present specification are not limited thereto. The first semiconductor layer 123 may include a channel area, a source area, and a drain area.

Since the polycrystalline semiconductor layer has higher mobility than the amorphous semiconductor layer and the oxide semiconductor layer, power consumption can be less, and reliability can be excellent. Accordingly, a driving transistor may be formed of the polycrystalline semiconductor layer.

A second insulating layer 104 may be disposed on the first semiconductor layer 123. The second insulating layer 104 may be formed of the same material as the first insulating layer 103 and can prevent a short circuit between the first semiconductor layer 123 and another component of the first thin film transistor 120.

The first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present specification are not limited thereto. The first gate electrode 122 may be disposed along with a gate line.

The third insulating layers 105-1 and 105-2 may be disposed on the first gate electrode 122. The third insulating layers 105-1 and 105-2 may be formed by alternately stacking silicon nitride (SiNₓ) and silicon oxide (SiOₓ) at least once, but the embodiments of the present specification are not limited thereto. For example, the 3-1 insulating layer 105-1 may include silicon oxide (SiOₓ), and the 3-2 insulating layer 105-2 may include silicon nitride (SiNₓ), but the embodiments of the present specification are not limited thereto.

The first source electrode 121 and the first drain electrode 124 may be disposed on the third insulating layers 105-1 and 105-2.

The first source electrode 121 and the first drain electrode 124 may be electrically connected to the first semiconductor layer 123 through contact holes. The first source electrode 121 and the first drain electrode 124 may be formed of a metallic material. For example, the first source electrode 121 and the first drain electrode 124 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto.

The first source electrode 121 and the first drain electrode 124 may be disposed along with a data line. For example, the data line may be formed of the same material as the first source electrode 121 and the first drain electrode 124 and formed on the same layer as the first source electrode 121 and the first drain electrode 124, but the embodiments of the present specification are not limited thereto.

A storage electrode 140 may be disposed to be spaced apart from the first thin film transistor 120. The storage electrode 140 may include a first storage electrode 141 and a second storage electrode 142.

The first storage electrode 141 may be formed of the same material as the first gate electrode 122 and disposed on the same layer as the first gate electrode 122, but the embodiments of the present specification are not limited thereto.

The second storage electrode 142 may be disposed on the first storage electrode 141. The second storage electrode 142 may be disposed on the third insulating layers 105-1 and 105-2, and the third insulating layers 105-1 and 105-2 between the first storage electrode 141 and the second storage electrode 142 may be used as a dielectric to generate a capacitance. The second storage electrode 142 may be formed of the same material as the first storage electrode 141, but the embodiments of the present specification are not limited thereto.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light-shielding layer 136 may be disposed on the same layer as the second storage electrode 142.

The second light-shielding layer 136 can prevent or at least reduce light from traveling to the second semiconductor layer 133 similar to the first light-shielding layer 126, thereby extending the life of the second thin film transistor 130. For example, the second semiconductor layer 133 may be disposed to overlap the second light-shielding layer 136.

The fourth insulating layer 106 may be disposed on the second light-shielding layer 136. The fourth insulating layer 106 may be formed of the same material as the first insulating layer 103, the second insulating layer 104, or the third insulating layers 105-1 and 105-2, but the embodiments of the present specification are not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon, polycrystalline silicon, etc., but the embodiments of the present specification are not limited thereto.

The fifth insulating layer 108 may be disposed on the second semiconductor layer 133. The fifth insulating layer 108 may be formed of the same material as the first insulating layer 103, the second insulating layer 104, the third insulating layers 105-1 and 105-2, or the fourth insulating layer 106, but the embodiments of the present specification are not limited thereto.

The second gate electrode 132 may be disposed on the fifth insulating layer 108.

The second gate electrode 132 may be formed of the same material as the first gate electrode 122. For example, the second gate electrode 132 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present specification are not limited thereto.

The sixth insulating layer 109 may be disposed on the second gate electrode 132. The sixth insulating layer 109 may be formed of the same material as the first insulating layer 103, the second insulating layer 104, the third insulating layers 105-1 and 105-2, the fourth insulating layer 106, or the fifth insulating layer 108, but the embodiments of the present specification are not limited thereto.

The first source electrode 121, the first drain electrode 124, the second source electrode 131, and the second drain electrode 134 may be disposed on the sixth insulating layer 109.

The second source electrode 131 and the second drain electrode 134 may be formed of the same material as the first source electrode 121 and the first drain electrode 124 and disposed on the same layer as the first source electrode 121 and the first drain electrode 124, but the embodiments of the present specification are not limited thereto. For example, the second source electrode 131 and the second drain electrode 134 may be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto. For example, the second source electrode 131 may be electrically connected to the second storage electrode 142. The second source electrode 131 may pass through the sixth insulating layer 109, the fifth insulating layer 108, and the fourth insulating layer 106 and may be electrically connected to the second storage electrode 142.

The first thin film transistor 120 may be a driving transistor, and the second thin film transistor 130 may be a switching transistor, but the embodiments of the present specification are not limited thereto.

A first protective layer 111 may be disposed on the first source electrode 121 and the first drain electrode 124.

The first protective layer 111 may planarize an upper portion of the first thin film transistor 120 and protect the first thin film transistor 120. The first protective layer 111 may be formed of an organic material. For example, the first protective layer 111 may be formed of an organic material including an acrylic resin, an epoxy resin, a phenolic resin, a polyamide resin, or a polyimide resin, but the embodiments of the present specification are not limited thereto.

The second protective layer 112 may be disposed on the first protective layer 111. The second protective layer 112 may be formed of the same material as the first protective layer 111, but the embodiments of the present specification are not limited thereto.

In some embodiments, a third protective layer may be further disposed on an upper surface of the second protective layer 113, but the embodiments of the present specification are not limited thereto.

A connection electrode 145 may be disposed between the first protective layer 111 and the second protective layer 112.

The connection electrode 145 may electrically connect the first thin film transistor 120 to the light-emitting part 150. The connection electrode 145 may be formed of the same material as the first source electrode 121 and the first drain electrode 124, but the embodiments of the present specification are not limited thereto.

The connection electrode 145 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto.

The light-emitting part 150 may be disposed on the second protective layer 112. The light-emitting part 150 may include a first electrode 151, an organic layer 152, and a second electrode 153. The first electrode 151 may serve as an anode, and the second electrode 153 may serve as a cathode.

The first electrode 151 may be disposed on the second protective layer 112. The first electrode 151 may be electrically connected to the first thin film transistor 120 through a contact hole formed in the second protective layer 112. The first electrode 151 may be a reflective electrode that reflects light, but the embodiments of the present specification are not limited thereto. The first electrode 151 may include a metallic material with high reflectance, such as a stacking structure (Ti/Al/Ti) of aluminum (Al) and titanium (Ti), a stacking structure (ITO/Al/ITO) of aluminum (Al) and indium tin oxide (ITO), or an APC alloy and may be formed of a single layer or multiple layers, but the embodiments of the present specification are not limited thereto.

The organic layer 152 may be disposed on the first electrode 151. The organic layer 152 may include one or more light-emitting structures (or light-emitting elements or elements) stacked on the first electrode 151 in the order or reverse order of a hole transfer layer and an electron transfer layer. For example, the hole transfer layer may include a hole transporting layer, a hole injecting layer, an electron blocking layer, a p-type charge generation layer, etc., but the embodiments of the present specification are not limited thereto. For example, the electron transfer layer may include an electron transporting layer, an electron injecting layer, a hole blocking layer, an n-type charge generation layer, etc., but the embodiments of the present specification are not limited thereto. The organic layer 152 may be an organic light-emitting layer, an inorganic light-emitting layer, a quantum dot light-emitting layer, a micro light-emitting diode, a micro mini light-emitting diode, etc., but the embodiments of the present specification area not limited thereto. For example, the organic layer 152 of the display panel 100 according to one embodiment of the present specification may include an organic light-emitting layer. The organic layer 152 may include a red light-emitting layer, a green light-emitting layer, and a blue light-emitting layer. The organic layer 152 may be a white light-emitting layer, but the embodiments of the present specification are not limited thereto. Hereinafter, a specific structure of the organic layer 152 according to one embodiment will be described.

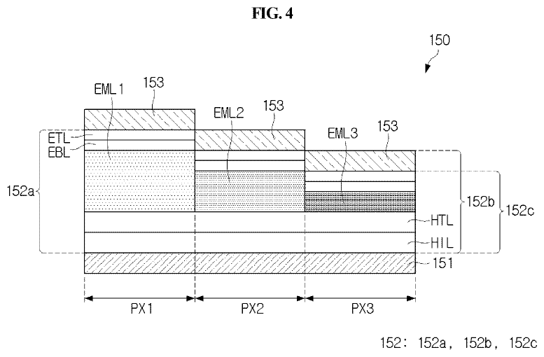

FIG. 4 is a specific cross-sectional view of a light-emitting part of FIG. 3 according to one embodiment.

Referring to FIG. 4, the light-emitting part 150 may include the first sub-pixel PX1, the second sub-pixel PX2, and the third sub-pixel PX3.

A thickness of the light-emitting part 150 in each sub-pixel PX1, PX2, or PX3 may be different, but the embodiments of the present specification are not limited thereto, and the thickness of the light-emitting part 150 in each sub-pixel PX1, PX2, or PX3 may be the same.

The organic layer 152 may include a first organic layer 152a disposed in the first sub-pixel PX1, a second organic layer 152b disposed in the second sub-pixel PX2, and a third organic layer 152c disposed in the third sub-pixel PX3. The light-emitting layers EML1, EML2, and EML3 of the organic layers 152a, 152b, and 152c may be physically separated, but lower layers and upper layers of the light-emitting layers EML1, EML2, and EML3 may be formed integrally across the sub-pixels PX1, PX2, and PX3. A thicknesses of each light-emitting layer EML1, EML2, or EML3 may be different. For example, a thickness of a first light-emitting layer EML1 may be the greatest, a thickness of a second light-emitting layer EML2 may be the second greatest, and a thickness of the third light-emitting layer EML3 may be the smallest, but the embodiments of the present specification are not limited thereto.

A hole injecting layer HIL may be disposed on the first electrode 151. The hole injecting layer HIL may be located between the first electrode 151 and the light-emitting layers EML1, EML2, and EML3. The hole injecting layer HIL may be formed integrally across the sub-pixels PX1, PX2, and PX3. For example, the hole injecting layer HIL may be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present specification are not limited thereto.

A hole transporting layer HTL may be disposed on the hole injecting layer HIL. The hole transporting layer HTL may be located between the hole injecting layer HIL and the light-emitting layers EML1, EML2, and EML3. The hole transporting layer HTL may be formed integrally across the sub-pixels PX1, PX2, and PX3. The hole transporting layer HTL may be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthylN,N′-diphenyl benzidine), s-TAD, and MTDATA(4,4′,4″-Tris(N-3-methylphenyl-N-phenyl-amino)-triphenylamine), but the embodiments of the present specification are not limited thereto.

The light-emitting layers EML1, EML2, and EML3 may be disposed on the hole transporting layer HTL. The first light-emitting layer EML1 may be disposed in the first sub-pixel PX1, the second light-emitting layer EML2 may be disposed in the second sub-pixel PX2, and the third light-emitting layer EML3 may be disposed in the third sub-pixel PX3.

A thicknesses of each light-emitting layer EML1, EML2, or EML3 may be different. For example, the first light-emitting layer EML1 may be formed in a thickness of 600 Å to 800 Å, the second light-emitting layer EML2 may be formed in a thickness of 300 Å to 500 Å, and the third light-emitting layer EML3 may be formed in a thickness of 100 Å to 300 Å, but the embodiments of the present specification are not limited thereto.

Each of the first light-emitting layer EML1, the second light-emitting layer EML2, and the third light-emitting layer EML3 may include a material that may emit light in the visible light range by receiving and combining holes and electrons.

An electron blocking layer EBL may be disposed on each light-emitting layer EML1, EML2, or EML3. The electron blocking layer EBL may be disposed integrally across the sub-pixels PX1, PX2, and PX3.

An electron transporting layer ETL may be disposed on the electron blocking layer EBL. The electron transporting layer ETL may be disposed integrally across the sub-pixels PX1, PX2, and PX3. The electron transporting layer ETL may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present specification are not limited thereto.

The second electrode 153 may be disposed on the electron transporting layer ETL.

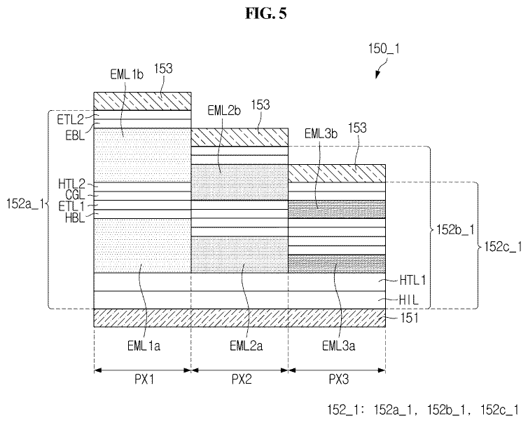

FIG. 5 is a specific cross-sectional view of a light-emitting part according to a modified example according to one embodiment.

Referring to FIGS. 4 and 5, an organic layer 152_1 may include a first organic layer 152a_1 disposed in the first sub-pixel PX1, a second organic layer 152b_1 disposed in the second sub-pixel PX2, and a third organic layer 152c_1 disposed in the third sub-pixel PX3.

The light-emitting layers of each organic layer 152a_1, 152b_1, or 152c_1 may be physically separated, but the lower layers and upper layers of the light-emitting layers may be formed integrally across the sub-pixels PX1, PX2, and PX3. The thickness of each light-emitting layer may be different. For example, the thickness of the first light-emitting layer of the first sub-pixel may be the greatest, the thickness of the second light-emitting layer of the second sub-pixel may be the second greatest, and the thickness of the third light-emitting layer of the third sub-pixel may be the smallest, but the embodiments of the present specification are not limited thereto. In addition, the light-emitting layers of each organic layer 152a_1, 152b_1, or 152c_1 may be provided as two or more light-emitting layers.

A hole injecting layer HIL may be disposed on the first electrode 151. The hole injecting layer HIL may be located between the first electrode 151 and the light-emitting layers EML1a, EML2a, and EML3a. The hole injecting layer HIL may be formed integrally across the sub-pixels PX1, PX2, and PX3. For example, the hole injecting layer HIL may be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present specification are not limited thereto.

A first hole transporting layer HTL1 may be disposed on the hole injecting layer HIL. The first hole transporting layer HTL1 may be located between the hole injecting layer HIL and light-emitting layers EML1a, EML2a, and EML3a. The first hole transporting layer HTL1 may be formed integrally across the sub-pixels PX1, PX2, and PX3. The first hole transporting layer HTL1 may be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthylN,N′-diphenyl benzidine), s-TAD, and MTDATA(4,4 ,4″-Tris(N-3-methylphenyl-N-phenyl-amino)-triphenylamine), but the embodiments of the present specification are not limited thereto.

The light-emitting layers EML1a, EML2a, and EML3a may be disposed on the first hole transporting layer HTL1. A 1-1 light-emitting layer EML1a may be disposed in the first sub-pixel PX1, a 2-1 light-emitting layer EML2a may be disposed in the second sub-pixel PX2, and a 3-1 light-emitting layer EML3a may be disposed in the third sub-pixel PX3. Each of the light-emitting layers EML1a, EML2a, and EML3a may be the same as each of the light-emitting layers EML1, EML2, and EML3 of FIG. 4.

A thicknesses of each light-emitting layer EML1a, EML2a, or EML3a may be different. For example, the 1-1 light-emitting layer EML1a may be formed in a thickness of 600 Å to 800 Å, the 2-1 light-emitting layer EML2a may be formed in a thickness of 300 Å to 500 Å, and the 3-1 light-emitting layer EML3a may be formed in a thickness of 100 Å to 300 Å, but the embodiments of the present specification are not limited thereto.

A hole blocking layer HBL may be disposed on each light-emitting layer EML1a, EML2a, or EML3a. The hole blocking layer HBL may be disposed integrally across the sub-pixels PX1, PX2, and PX3.

A first hole transporting layer ETL1 may be disposed on the hole blocking layer HBL. The first electron transporting layer ETL1 may be formed integrally across the sub-pixels PX1, PX2, and PX3. The first electron transporting layer ETL1 may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present specification are not limited thereto.

A common charge layer CGL may be disposed on the first electron transporting layer ETL1. The common charge layer CGL may be disposed between the first electron transporting layer ETL1 and the second hole transporting layer HTL2. The common charge layer CGL may include a conductive material, but the embodiments of the present disclosure are not limited thereto.

A second hole transporting layer HTL2 may be disposed on the common charge layer CGL. The second hole transporting layer HTL2 may be disposed between the hole blocking layer HBL and the light-emitting layers EML1b, EML2b, and EBL3b. The second hole transporting layer HTL2 may be formed integrally across the sub-pixels PX1, PX2, and PX3. A material of the second hole transporting layer HTL2 may be the same as a material of the first hole transporting layer HTL1, but the embodiments of the present specification are not limited thereto.

The light-emitting layers EML1b, EML2b, and EML3b may be disposed on the second hole transporting layer HTL2. A 1-2 light-emitting layer EML1b may be disposed in the first sub-pixel PX1, a 2-2 light-emitting layer EML2b may be disposed in the second sub-pixel PX2, and a 3-2 light-emitting layer EML3b may be disposed in the third sub-pixel PX3. Each of the light-emitting layers EML1b, EML2b, and EML3b may be the same as each of the light-emitting layers EML1a, EML2a, and EML3a.

A thicknesses of each light-emitting layer EML1b, EML2b, or EML3b may be different. For example, the 1-2 light-emitting layer EML1b may be formed in a thickness of 600 to 800 Å, the 2-2 light-emitting layer EML2b may be formed in a thickness of 300 to 500 Å, and the 3-2 light-emitting layer EML3b may be formed in a thickness of 100 to 300 Å, but the embodiments of the present specification are not limited thereto.

An electron blocking layer EBL may be disposed on each light-emitting layer EML1b, EML2b, or EML3b. The electron blocking layer EBL may be disposed integrally across the sub-pixels PX1, PX2, and PX3.

A second hole transporting layer ETL2 may be disposed on the electron blocking layer EBL. The second electron transporting layer ETL2 may be formed integrally across the sub-pixels PX1, PX2, and PX3. The second electron transporting layer ETL2 may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present specification are not limited thereto.

The second electrode 153 may be disposed on the second electron transporting layer ETL2.

Referring back to FIG. 3, the second electrode 153 may be disposed on the organic layer 152. The second electrode 153 may be a transparent electrode that transmits light, but the embodiments of the present specification are not limited thereto. For example, the second electrode 153 may include a transparent conductive material, such as indium tin oxide (ITO) or indium zinc oxide (IZO), or a metal that transmits visible light, but the embodiments of the present specification are not limited thereto.

The bank 154 may be disposed to expose the first electrode 151. The bank 154 may define openings (or the light-emitting areas EA1, EA2, and EA3) of the sub-pixels PX1, PX2, and PX3 and may be disposed to cover an edge portion (or a periphery) of the first electrode 151. That is, the first sub-pixel PX1 may include a first light-emitting area EA1 and a first non-light-emitting area NEA1 around the first light-emitting area EA1, the second sub-pixel PX2 may include a second light-emitting area EA2 and a second non-light-emitting area NEA2 around the second light-emitting area EA2, and the third sub-pixel PX3 may include a third light-emitting area EA3 and a third non-light-emitting area NEA3 around the third light-emitting area EA3. That is, each non-light-emitting area NEA1, NEA2, or NEA3 may correspond to a boundary between adjacent sub-pixels PX1, PX2, and PX3.

The bank 154 may include a first bank 154a and a second bank 154b. In the present specification, the second bank 154b may also be referred to as a bank pattern, but the embodiments of the present specification are not limited thereto.

The first bank 154a may include a black-based material. For example, the first bank 154a may be formed of a material containing black pigment, or an organic material, such as a benzocyclobutene resin, a polyimide resin, an acrylic resin, a photosensitive polymer, etc., but the embodiments of the present specification are not limited thereto. When the first bank 154a is formed of a material containing black pigment or black dye, the first bank 154a may be a black bank. When the first bank 154a is formed of a material containing black pigment or black dye, it is possible to shield external light or light reflected from the outside, thereby further increasing the luminance of the display device.

The first bank 154a may include an upper surface and side surfaces. The upper surface of the first bank 154a may be flat in a horizontal direction, and the side surface of the first bank 154a may be tapered in a thickness direction.

The second bank 154b may be disposed on the side surfaces of the first bank 154a. The second bank 154b may expose a part of the upper surface of the first bank 154a. The second bank 154b may expose the entire upper surface of the first bank 154a, but the embodiments of the present specification are not limited thereto. The second bank 154b may not include a black-based material.

For example, the first bank 154a can suppress surface reflection of external light as described above. For example, the first bank 154a may absorb external light by including the black-based material. That is, the first bank 154a may include a resin, a black-based material in the resin, an additive for dispersing the black-based material in the resin, etc. For example, the resin may include an organic material, such as a benzocyclobutene resin, a polyimide resin, an acrylic resin, a photosensitive polymer, etc., and the additive may be, for example, a dispersant, but the embodiments of the present specification are not limited thereto.

The second bank 154b may include a material having a lower content of a black-based material among materials included in the first bank 154a or may not include the black-based material at all. For example, the second bank 154b may be a transparent bank, but the embodiments of the present specification are not limited thereto.

Hereinafter, an optical density is introduced to distinguish the materials of the first bank 154a and the second bank 154b.

The concept of the bank 154 absorbing external light is related to the optical density. The higher the optical density (hereinafter referred to as an “OD”), which is an index of a specific material absorbing light, the higher a light absorption rate. That is, the lower the OD, the higher the light transmittance. For example, the OD may be calculated using 1 μm as a reference thickness and proportional to a thickness. Hereinafter, the OD calculated using 1 μm as a reference thickness is referred to as a “reference OD.”

Since the second bank 154b includes less or no black-based material compared to the first bank 154a, the reference OD of the first bank 154a may be higher than the reference OD of the second bank 154b.

A barrier RAS may be further disposed on the first bank 154a. As illustrated in FIG. 3, the barrier RAS may be disposed at all the boundaries NEA1, NEA2, and NEA3 between the sub-pixels PX1, PX2, and PX3, but the embodiments of the present specification are not limited thereto. The barrier RAS may be disposed directly on the upper surface of the first bank 154a, but the embodiments of the present specification are not limited thereto. The barrier RAS may serve to separate the organic layer 152 from the boundaries of adjacent sub-pixels PX1, PX2, and PX3. In some embodiments, the barrier RAS is not disposed, and a trench may be formed on the first bank 154a. The first bank 154a may be recessed by the trench in the thickness direction.

A spacer 155 may be further disposed on the first bank 154a. The spacer 155 may be formed of the same material as the second bank 154b, but the embodiments of the present specification are not limited thereto. For example, the spacer 155 may be a transparent bank, but is not limited thereto, and may be formed of the same material as the first bank 154a. For example, the spacer 155 may be disposed on at least one of the boundaries of the first to third sub-pixels PX1, PX2, and PX3, but the embodiments of the present specification are not limited thereto. The second bank 154b and the spacer 155 may be formed of the same material and formed simultaneously through a halftone mask or slit, but the embodiments of the present specification are not limited thereto.

The organic layer 152 may be disposed on the first electrode 151, the bank 154, and the spacer 155. The second electrode 153 may be disposed on the organic layer 152.

The encapsulation part 170 may be disposed on the second electrode 153. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic insulation material layers and one or more organic material layers. For example, the first encapsulation layer 171 and the third encapsulation layer 173 may include an inorganic insulation material, and the second encapsulation layer 172 may include an organic material, but the embodiments of the present specification are not limited thereto.

The touch part 180 may be disposed on the encapsulation part 170. The touch part 180 may include the touch buffer layer 181, a first touch conductive layer, the first touch insulating layer 183, the second touch insulating layer 184, and a second touch conductive layer. In some embodiments, one or more touch organic layers may be further disposed on the second touch conductive layer, but the embodiments of the present specification are not limited thereto.

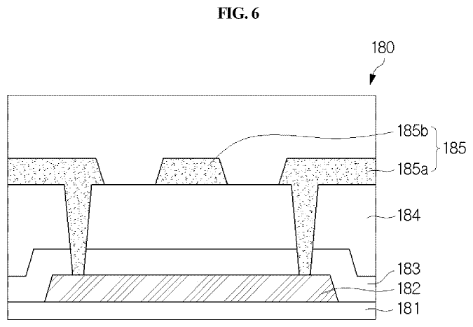

FIG. 6 is a cross-sectional view of a touch part according to FIG. 3 according to one embodiment.

Referring to FIGS. 3 and 6, the touch buffer layer 181 may be disposed on the encapsulation part 170. For example, a touch buffer layer 181 may be disposed on the third encapsulation layer 173. The touch buffer layer 181 may be formed of the same material as the buffer layer 102, but the embodiments of the present specification are not limited thereto.

The first touch conductive layer may be disposed on the touch buffer layer 181. The first touch conductive layer may include a bridge electrode 182. The bridge electrode 182 and a sensor electrode 185 to be described below may be disposed at each of the boundaries between adjacent sub-pixels PX1, PX2, and PX3. For example, the bridge electrode 182 and the sensor electrode 185 may be disposed in the non-light-emitting areas NEA1, NEA2, and NEA3. The bridge electrode 182 and the sensor electrode 185 may overlap the black matrix BM to be described below in the thickness direction. The black matrix BM may cover the bridge electrode 182 and the sensor electrode 185. Accordingly, the bridge electrode 182 and the sensor electrode 185 can be prevented from being visible from the outside.

The first touch insulating layer 183 and the second touch insulating layer 184 disposed on the first touch insulating layer 183 may be disposed on the first touch conductive layer. The first touch insulating layer 183 and the second touch insulating layer 184 disposed on the first touch insulating layer 183 can prevent a short circuit between the first touch conductive layer and the second touch conductive layer. The first touch insulating layer 183 may be formed of silicon oxide (SiOₓ), silicon nitride (SiNₓ), or multiple layers thereof, but the embodiments of the present specification are not limited thereto. The second touch insulating layer 184 may include an organic insulation material, but the embodiments of the present specification are not limited thereto, and the second touch insulating layer 184 may include the same material as the first touch insulating layer 183.

The second touch conductive layer may be disposed on the second touch insulating layer 184. The second touch conductive layer may include a first sensor electrode 185a and a second sensor electrode 185b. The sensor electrode 185 may include the first sensor electrode 185a extending in the first direction DR1 (see FIG. 1) and the second sensor electrode 185b extending in the second direction DR2 (see FIG. 1) different from the first direction DR1.

The bridge electrode 182 may be electrically connected to the first sensor electrode 185a through a contact hole formed in the first touch insulating layer 183 and the second touch insulating layer 184. For example, the first sensor electrode 185a and the bridge electrode 182 may extend in the first direction DR1 (see FIG. 1).

The sensor electrode 185 and the bridge electrode 182 may include a metallic material. For example, the sensor electrode 185 and the bridge electrode 182 may be formed of titanium (Ti), nickel (Ni), aluminum (Al), or an alloy thereof and formed of a triple layer, such as titanium (Ti)/aluminum (Al)/titanium (Ti), but the embodiments of the present specification are not limited thereto.

Referring back to FIG. 3, the filter insulating layer 114 may be disposed on the second touch conductive layer. The filter insulating layer 114 may be formed of an inorganic insulation material, such as silicon nitride (SiNₓ) or silicon oxide (SiOₓ), but the embodiments of the present specification are not limited thereto.

The black matrix BM may be disposed on the filter insulating layer 114. The black matrix BM may include a black-based material. For example, the black matrix BM may include a light-blocking material or a light-absorbing material. For example, the black matrix BM may be formed of a material including a black pigment, a black dye, etc. The black matrix BM may cover the bridge electrode 182 and the sensor electrode 185. Accordingly, the bridge electrode 182 and the sensor electrode 185 can be prevented from being visible from the outside. For example, a width of the black matrix BM may be smaller than a width of the bank 154.

For example, spacing distances between an end of the black matrix BM and boundaries between the light-emitting areas EA1, EA2, and EA3 and the non-light-emitting areas NEA1, NEA2, and NEA3 may be longer than spacing distances between an end of the bank 154 and the boundaries between the light-emitting areas EA1, EA2, and EA3 and the non-light-emitting areas NEA1, NEA2, and NEA3. The end of the bank 154 may be aligned with the boundaries between the light-emitting areas EA1, EA2, and EA3 and the non-light-emitting areas NEA1, NEA2, and NEA3, but the embodiments of the present specification are not limited thereto. In the case of the display panel 100 according to one embodiment, since the bank 154 may include a black-based material and the spacing distances between an end of the black matrix BM and boundaries between the light-emitting areas EA1, EA2, and EA3 and the non-light-emitting areas NEA1, NEA2, and NEA3 may be longer than spacing distances between an end of the bank 154 and the boundaries between the light-emitting areas EA1, EA2, and EA3 and the non-light-emitting areas NEA1, NEA2, and NEA3, light emitted from the light-emitting areas EA1, EA2, and EA3 may be emitted upward with a greater viewing angle as much as a spacing space between the end of the black matrix BM and the boundaries between the light-emitting areas EA1, EA2, and EA3 and the non-light-emitting areas NEA1, NEA2, and NEA3. Accordingly, it is possible to minimize a reduction in luminance according to a viewing angle. However, when the spacing distances between an end of the black matrix BM and boundaries between the light-emitting areas EA1, EA2, and EA3 and the non-light-emitting areas NEA1, NEA2, and NEA3 may be longer than spacing distances between an end of the bank 154 and the boundaries between the light-emitting areas EA1, EA2, and EA3 and the non-light-emitting areas NEA1, NEA2, and NEA3 and the bank 154 is formed of only a transparent material, light incident from the outside may be reflected by the bank 154, resulting in visible ring-shaped spots. However, in the case of the display panel 100 according to one embodiment, the light incident from the outside may be absorbed or blocked by the bank 154 including a black-based material, thereby preventing the occurrence of the ring-shaped spots.

The color filters 191, 192, and 193 may be disposed on the black matrix BM. The color filters 191, 192, and 193 may be disposed on the first to third sub-pixels PX1, PX2, and PX3, respectively, and may block specific colors from light emitted from the light-emitting area EA1, EA2, and EA3 of the sub-pixels PX1, PX2, and PX3. The first color filter 191 may be provided to block light of other colors not including red (R) light. In this case, the first color filter 191 may be provided as a red color filter. The second color filter 192 may be provided to block light of other colors not including green (G) light. In this case, the second color filter 192 may be provided as a green color filter. A third color filter 193 provided in the third sub-pixel PX3 may be provided to block light of other colors not including blue (B) light. In this case, the third color filter 193 may be provided as a blue color filter. However, the embodiments of the present specification are not limited thereto.

For example, each color filter 191, 192, or 193 may come into direct contact with side and upper surfaces of the black matrix BM. For example, each color filter 191, 192, or 193 may be spaced apart from the boundaries of adjacent sub-pixels PX1, PX2, and PX3, but the embodiments of the present specification are not limited thereto, and the color filters 191, 192, and 193 may overlap each other in the thickness direction.

The planarization layer OC may be disposed on the color filters 191, 192, and 193. The planarization layer OC may serve to planarize a step formed by the color filters 191, 192, and 193. For example, the planarization layer OC may include an organic insulation material.

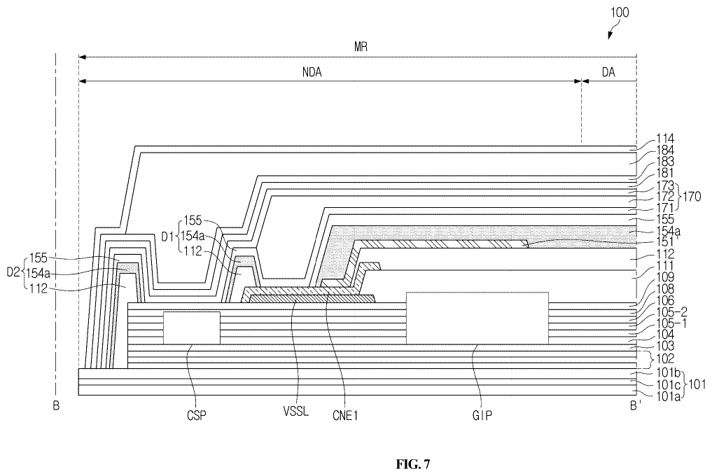

FIG. 7 is a cross-sectional view along line B-B′ in FIG. 1 according to one embodiment.

Referring to FIG. 7, at least one of the panel inorganic layers 102, 103, 104, 105-1, 105-2, 106, 108, and 109 may not extend to an end portion of the substrate 101. That is, the at least one of the panel inorganic layers 102, 103, 104, 105-1, 105-2, 106, 108, and 109 may expose the end portion of the substrate 101, but the embodiments of the present specification are not limited thereto.

The display panel 100 according to one embodiment may further include the crack sensing pattern CSP, the low-potential voltage line VSSL, and the gate driving unit GIP. As described above in FIG. 1, the low-potential voltage line VSSL may be located between the crack sensing pattern CSP and the display area DA, and the gate driving unit GIP may be located between the low-potential voltage line VSSL and the display area DA.

For example, as illustrated in FIG. 7, the gate driving unit GIP may be formed of a conductive layer located on the same layer as the first gate electrode 122 (see FIG. 3), a conductive layer located on the same layer as the second light-shielding layer 136 (see FIG. 3), or a conductive layer located on the same layer as the first source electrode 121, but the embodiments of the present specification are not limited thereto.

For example, the crack sensing pattern CSP may be disposed between a first dam D1 and a second dam D2. The crack sensing pattern CSP may be formed of a conductive layer located on the same layer as the first gate electrode 122 (see FIG. 3) or a conductive layer located on the same layer as the second light-shielding layer 136 (see FIG. 3), but the embodiments of the present specification are not limited thereto. For example, the crack sensing pattern CSP may include a conductive layer located on the same layer as the first source electrode 121, but the embodiments of the present specification are not limited thereto.

The low-potential voltage line VSSL may be disposed between the crack sensing pattern CSP and the gate driving unit GIP. The low-potential voltage line VSSL may be formed of a conductive layer located on the same layer as the first source electrode 121, but the embodiments of the present specification are not limited thereto.

The first protective layer 111 may cover the gate driving unit GIP, partially cover one end portion of the low-potential voltage line VSSL and expose the other end portion of the low-potential voltage line VSSL. In the present specification, the one end portion may refer to an area of a certain component, which is located in a direction from the non-display area NDA toward the display area DA, and the other end portion may refer to an area of the certain component, which is located in a direction from the display area DA toward the non-display area NDA.

A first connection electrode CNE1 located on the same layer as the connection electrode 145 may be disposed on the first protective layer 111. The first connection electrode CNE1 may be directly connected to an area of the low-potential voltage line VSSL, in which the first protective layer 111 is exposed. The first connection electrode CNE1 may cover the other end portion of the low-potential voltage line VSSL, but the embodiments of the present specification are not limited thereto.

The second protective layer 112 may be disposed on the first connection electrode CNE1. The second protective layer 112 may come into direct contact with and cover one end portion of the first connection electrode CNE1 and expose the other end portion of the first connecting electrode CNE1. The second protective layer 112 may form a first layer of the first dam D1 and a first layer of the second dam D2. The second dam D2 may overlap, for example, the low-potential voltage line VSSL and cover the other end portion of the low-potential voltage line VSSL. The second dam D2 may come into direct contact with the first connection electrode CNE1 and cover the other end portion of the first connection electrode CNE1. The second protective layer 112 forming the first layer of the first dam D1 may come into direct contact with the exposed side surfaces of at least one of the panel inorganic layers 102, 103, 104, 105, 106, 107, and 109 and may come into direct contact with the upper surface of the substrate 101, but the embodiments of the present specification are not limited thereto. The second protective layer 112 may overlap the gate driving unit GIP. In the present specification, the dam is, for example, provided as two dams, but the dam may be provided as three or more dams or one dam.

A low-potential connection electrode 151′ located on the same layer as the first electrode 151 (see FIG. 3) may be disposed on the first connection electrode CNE1 exposed by the second protective layer 112 and the second protective layer 112. The low-potential connection electrode 151′ may be electrically connected to the first connection electrode CNE1 exposed by the second protective layer 112. The low-potential connection electrode 151′ may be electrically connected to the second electrode 153 (see FIG. 3) described above in FIG. 3.

The first bank 154a may be disposed on the low-potential connection electrode 151′ and the second protective layer 112. The first bank 154a may overlap the gate driving unit GIP, overlap the low-potential connection electrode 151′, and cover the other end portion of the low-potential connection electrode 151′. The first bank 154a may completely cover the low-potential connection electrode 151′, but the embodiments of the present specification are not limited thereto. The first bank 154a may expose a central portion and the other end portion of the first connection electrode CNE1, but the embodiments of the present specification are not limited thereto. The first bank 154a may form a second layer of the first dam D1 and a second layer of the second dam D2. In each dam D1 or D2, the first bank 154a may overlap the second protective layer 112 forming the first layer and completely cover the second protective layer 112, but the embodiments of the present specification are not limited thereto. In the second dam D2, the first bank 154a may come into contact with the side surfaces of the second protective layer 112 and the upper surface of the substrate 101, but the embodiments of the present specification are not limited thereto.

The spacer 155 may be disposed on the first bank 154a. The spacer 155 may overlap the gate driving unit GIP. The spacer 155 may form a third layer of the dams D1 and D2. The spacer 155 forming the third layer of each dam D1 or D2 may overlap the first bank 154a forming the second layer and completely cover the first bank 154a, but the embodiments of the present specification are not limited thereto. In the second dam D2, the spacer 155 may come into contact with the side surfaces of the first bank 154a and the upper surface of the substrate 101, but the embodiments of the present specification are not limited thereto.

The encapsulation part 170 may be disposed on the spacer 155. The first encapsulation layer 171 may extend to the gate driving unit GIP, the low-potential voltage line VSSL, the first dam D1, and the second dam D2 and cover an outer surface of the second dam D2. The second encapsulation layer 172 may end at the first dam D1. The second encapsulation layer 172 may overlap the gate driving unit GIP and the low-potential voltage line VSSL. The third encapsulation layer 173 may extend to the gate driving unit GIP, the low-potential voltage line VSSL, the first dam D1, and the second dam D2 and come into direct contact with the first encapsulation layer 171 on the first dam D1, the crack sensing pattern CSP, and the second dam D2.

The touch buffer layer 181 and the first touch insulating layer 183 may extend to the gate driving unit GIP, the low-potential voltage line VSSL, the first dam D1, and the second dam D2 and cover the outer surface of the second dam D2. The second touch insulating layer 184 may extend to the gate driving unit GIP, the low-potential voltage line VSSL, the first dam D1, and the crack sensing pattern CSP and end on the second dam D2, but the embodiments of the present specification are not limited thereto.

The filter insulating layer 184 may extend to the gate driving unit GIP, the low-potential voltage line VSSL, the first dam D1, and the second dam D2 and come into direct contact with an outer surface of the second touch insulating layer 184, but the embodiments of the present specification are not limited thereto.

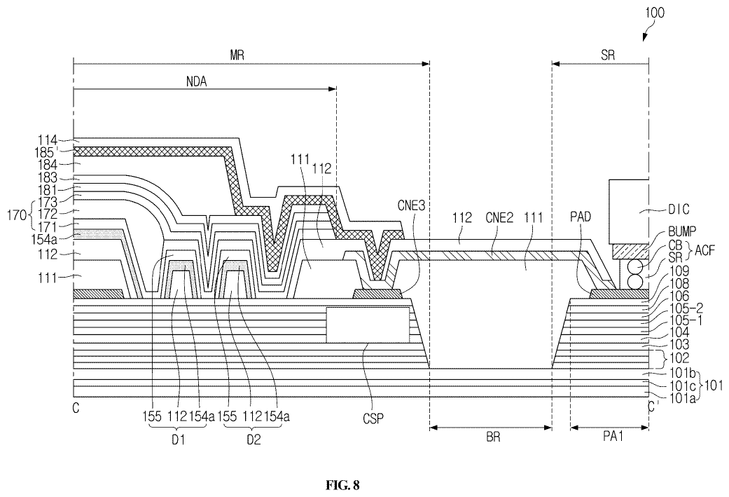

FIG. 8 is a cross-sectional view along line C-C′ in FIG. 1 according to one embodiment.

Referring to FIGS. 3, 7, and 8, the bending region BR may be disposed between the sub-region SR and the crack sensing pattern CSP. In the bending region BR, the panel inorganic layers 102, 103, 104, 105, 106, 107, and 109 may be removed to expose the upper surface of the substrate 101.

In the first pad area PA1, a pad electrode PAD disposed on the same layer as the first source electrode 121 (see FIG. 3) may be disposed, and a third connection electrode CNE3 disposed on the same layer as the first source electrode 121 (see FIG. 3) may be disposed on the crack sensing pattern CSP.

The first protective layer 111 may be disposed on the pad electrode PAD and the third connection electrode CNE3. The first protective layer 111 may be disposed in the bending region BR, and the first protective layer 111 may come into direct contact with the upper surface of the substrate 101 and in the bending region BR, the first protective layer 111 may come into direct contact with the side surfaces of the panel inorganic layers 102, 103, 104, 105, 106, 107, and 109.

A second connection electrode CNE2 may be disposed on the first protective layer 111, and the second connection electrode CNE2 may be disposed on the same layer as the connection electrode 145 (see FIG. 3). The second connection electrode CNE2 may electrically connect the pad electrode PAD to the third connection electrode CNE3. The second connection electrode CNE2 may be disposed on the bending region BR and may also be disposed on the first pad area PA1 and the crack sensing pattern CSP.

The data driving unit DIC may be disposed on the pad electrode PAD. The data driving unit DIC may include a bump BUMP, an anisotropic conductive film ACF may be disposed between the pad electrode PAD and the bump BUMP, and the anisotropic conductive film ACF may electrically connect the pad electrode PAD to the bump BUMP. The anisotropic conductive film ACF may include a resin RS and a plurality of conductive balls CB dispersed in the resin RS. The pad electrode PAD and the bump BUMP may be electrically connected through the conductive balls CB.

The second protective layer 112 may be disposed on the second connection electrode CNE2. The second protective layer 112 may expose the pad electrode PAD.

The first and second encapsulation layers 171 and 173 of the encapsulation part 170 may extend until before the bending region BR. For example, the first and second encapsulation layers 171 and 173 may extend until before the crack sensing pattern CSP, but the embodiments of the present specification are not limited thereto, and the first and second encapsulation layers 171 and 173 may also overlap the crack sensing pattern CSP. The first and second encapsulation layers 171 and 173 may not be disposed in the bending region BR.

The touch buffer layer 181 and the first touch insulation layer 183 may extend until before the bending region BR. For example, the touch buffer layer 181 and the first touch insulating layer 183 may extend until before the crack sensing pattern CSP, but the embodiments of the present specification are not limited thereto, and the touch buffer layer 181 and the first touch insulating layer 183 may also overlap the crack sensing pattern CSP. The touch buffer layer 181 and the first touch insulation layer 183 may not be disposed in the bending region BR.

The second touch insulating layer 184 may overlap the first dam D1 and the second dam D2. The second touch insulating layer 184 may not be disposed outside the second dam D2, but the embodiments of the present specification are not limited thereto.

A touch connection line 185′ may be electrically connected to the second connection electrode CNE2. The touch connection line 185′ may serve to provide a signal applied from the pad electrode PAD and the second connection electrode CNE2 to the first sensor electrode 185a or the second sensor electrode 185b described above in FIG. 3. The touch connection line 185′ may be located on the same layer as the second touch conductive layer (the first sensor electrode 185a of FIG. 3), but the embodiments of the present specification are not limited thereto, and the touch connection line 185′ may be located on the same layer as the first touch conductive layer (the bridge electrode 182 of FIG. 3) or formed of two first and second touch conductive layers, but the embodiments of the present specification are not limited thereto.

The filter insulating layer 114 may be disposed on the touch connection line 185′, and the filter insulating layer 114 may not be disposed in the bending region BR.

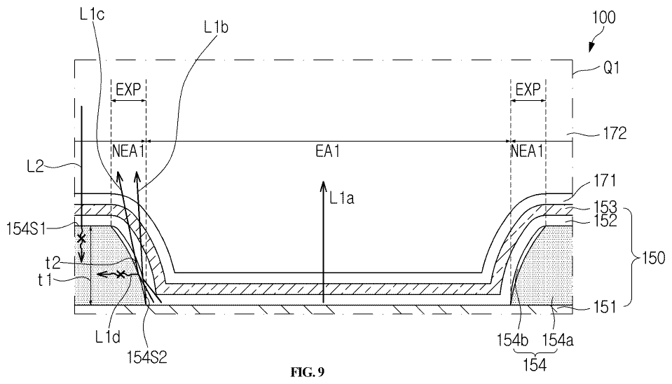

FIG. 9 is an enlarged cross-sectional view of area Q1 in FIG. 3 according to one embodiment.

In FIG. 9, the first sub-pixel PX1 is illustrated. Referring to FIGS. 3 and 9, the first bank 154a may include an upper surface 154S1 and a side surface 154S2. The second bank 154b may completely cover the side surface 154S2 of the first bank 154a and expose the upper surface 154S1. The second bank 154b may expose the upper surface 154S1 of the first bank 154a so that external light is absorbed by the first bank 154a, thereby improving surface reflection or external light reflection.

The first bank 154a may have a first thickness t1, and the second bank 154b may have a second thickness t2. In the present specification, the thicknesses t1 and t2 may refer to a maximum thickness of each bank 154a or 154b. For example, the first thickness t1 refers to a maximum thickness in an upward direction of the first bank 154a, and the second thickness t2 refers to a maximum thickness in a lateral direction of the second bank 154b. The second bank 154b may extend, for example, from one end (an end portion in contact with the first electrode 151) of the side surface 154S2 of the first bank 154a to the other end (an end portion in contact with the side surface 154S2 and the upper surface 154S1). The second bank 154b may cover lower and upper end portions of the side surface 154S2 of the first bank 154a. The second bank 154b may come into direct contact with the side surface of the first bank 154a.

Since the second bank 154b exposes the upper surface of the first bank 154a, external light L2 may be absorbed by the first bank 154a. Accordingly, it is possible to improve the external light reflection (or the surface reflection) of the display device.

In addition, the second bank 154b of the display panel 100 according to one embodiment may serve to extract some of the light emitted from the first light-emitting area EA1 upward.

For example, the organic layer 152 may emit light. For example, the organic layer 152 may emit light in the first light-emitting area EA1. Some light L1a of the light emitted from the organic layer 152 may travel upward. When the second bank 154b is not disposed, the other light of the light emitted from the organic layer 152, which travel toward the first bank 154a, may be absorbed by the first bank 154a.

However, in the case of the display panel 100 according to one embodiment, the other light emitted toward the first bank 154a may be emitted upward, thereby improving the light extraction effect of the display panel 100. L1b and L1c in FIG. 9 denote light that is emitted to the organic layer 152 of the first light-emitting area EA1 but travels toward the first bank 154a.

For example, some light L1b emitted from the first light-emitting area EA1 may be reflected from the surfaces of the organic layer 152 and the second bank 154b and extracted upward.

In addition, light incident on the second bank 154b from the organic layer 152 may travel in the second bank 154b and then may be incident on the first bank 154a and absorbed by the first bank 154a (see L1d in FIG. 9), but may be reflected from the surfaces of the second bank 154b and the first bank 154a and extracted upward (see L1c in FIG. 9).

Like L1b and L1c in FIG. 9, light may be extracted from the first non-light-emitting area NEA1 rather than the first light-emitting area EA1. That is, the first non-light-emitting area NEA1 may include an extra light extraction area EXP. The extra light extraction area EXP may be an area in contact with the first light-emitting area EA1. When the extra light extraction area EXP is spaced apart from the first light-emitting area EA1, the light recognized by the extra light extraction area EXP may be recognized as a ring-shaped spot that is spaced apart from the first light-emitting area EA1 and surrounds the first light-emitting area EA1. Accordingly, the extra light extraction area EXP comes into contact with the first light-emitting area EA1, and to this end, the second bank 154b forming the extra light extraction area EXP covers a lower end portion of the side surface 154S2 of the first bank 154a according to one embodiment. The extra light extraction area EXP may not overlap the black matrix BM, but may partially overlap the black matrix BM.

Furthermore, the second thickness t2 of the second bank 154b ranges from about ⅙ to about ⅔ times the first thickness t1 in one embodiment. For example, when the second thickness t2 is less than about ⅙ times the first thickness t1, the second thickness t2 of the second bank 154b may be too small so that light traveling toward the first bank 154a may not be reflected from the surfaces of the second bank 154b and the organic layer 152 (L1b of FIG. 9 does not occur), and in terms of a process, it may be difficult to form a small second thickness t2.

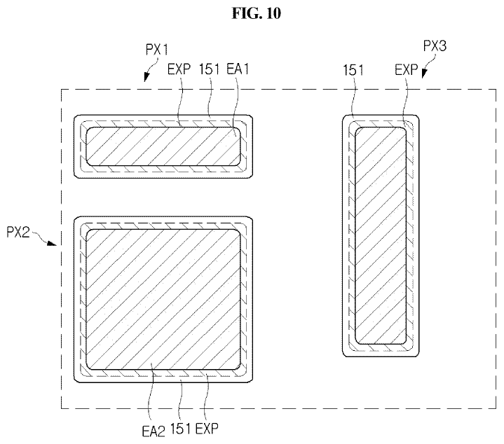

FIG. 10 is a plan view of a pixel according to one embodiment.

Referring to FIGS. 9 and 10, as described above, each non-light-emitting area NEA1, NEA2, or NEA3 may further include the extra light extraction area EXP by the second bank 154b. Since the second bank 154b extends from the lower end portion of the first bank 154a, the extra light extraction area EXP may be formed to be in contact with each light-emitting area EA1, EA2, or EA3 as illustrated in FIG. 10.

Hereinafter, a display device according to other embodiments will be described. In the following embodiments, the detailed description of the reference numerals or components described in FIGS. 1 to 10 will be omitted, or the overlapping descriptions thereof will be omitted.

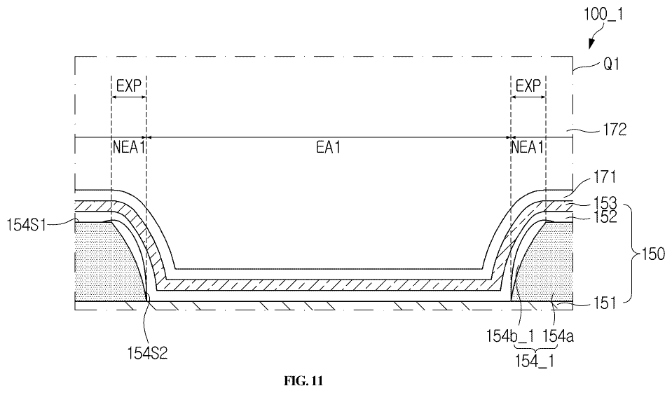

FIG. 11 is a cross-sectional view of a display device according to another embodiment.

Referring to FIG. 11, a display panel 100_1 of the display device according to the present embodiment differs from the display panel 100 according to FIG. 9 in that a second bank 154b_1 of a bank 154_1 may be disposed to extend to the upper surface 154S1 of the first bank 154a.

More specifically, the second bank 154b_1 may cover some of the upper surface 154S1 of the first bank 154a and expose the others of the upper surface 154S1.

Even in the present embodiment, since the second bank 154b_1 covers some of the upper surface 154S1 of the first bank 154a and exposes the others of the upper surface 154S1, external light may be absorbed by the first bank 154a, thereby improving surface reflection or external light reflection.

In addition, since the second bank 154b_1 covers the side surface 154S2 of the first bank 154a, some of the light that is emitted from the light-emitting areas EA1, EA2, and EA3 (see FIG. 3) and travels to the first bank 154a may be extracted upward, thereby increasing a light extraction rate.

Since the remaining parts have been described above in FIG. 9, the detailed descriptions thereof will be omitted.

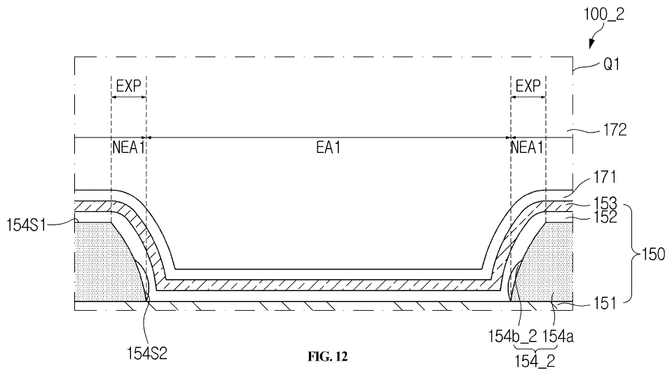

FIG. 12 is a cross-sectional view of a display device according to still another embodiment.

Referring to FIG. 12, a display panel 100_2 of the display device according to the present embodiment differs from the display panel 100 according to FIG. 9 in that a second bank 154b_2 of a bank 154_2 may cover the lower end portion of the first bank 154a and expose the upper end portion of the first bank 154a.

More specifically, the second bank 154b_1 may completely expose the upper surface 154S1 of the first bank 154a and cover the lower end portion of the side surface 154S.

Even in the present embodiment, the second bank 154b_2 may expose the upper surface 154S1 of the first bank 154a so that external light is absorbed by the first bank 154a, thereby improving surface reflection or external light reflection.

In addition, since the second bank 154b_2 covers the lower end portion of the side surface 154S2 of the first bank 154a, some of the light that is emitted from the light-emitting areas EA1, EA2, and EA3 (see FIG. 3) and travels to the first bank 154a may be extracted upward, thereby increasing a light extraction rate. In addition, the second bank 154b_2 may cover the lower end portion and expose the upper end portion of the side surface 154S2 of the first bank 154a. As described above in FIG. 9, some of the light that is emitted from the organic layer 152 of the first light-emitting area EA1 but travels toward the first bank 154a and is incident on the second bank 154b may be absorbed by the first bank 154a (see L1d in FIG. 9), reflected at a boundary between the first bank 154a and the second bank 154b, and extracted upward (see L1c in FIG. 9). However, some light may travel in a direction in which the second bank 154b extends inside the second bank 154b. The light traveling in the direction in which the second bank 154b extends may be emitted from the non-light-emitting area rather than the extra light extraction area EXP, and in this case, may be absorbed by the black matrix BM of FIG. 3.

However, there is an advantage in that the second bank 154b_2 according to the present embodiment may cover the lower end portion and expose the upper end portion of the side surface 154S2 of the first bank 154a, thereby increasing the light extraction rate in the extra light extraction area EXP.

For example, the second bank 154b_1 may be disposed in an area of the side surface 154S2 of the first bank 154a, which corresponds to about ½ of a length from one end (the end portion in contact with the first electrode 151).

Since the remaining parts have been described above in FIG. 9, the detailed descriptions thereof will be omitted.

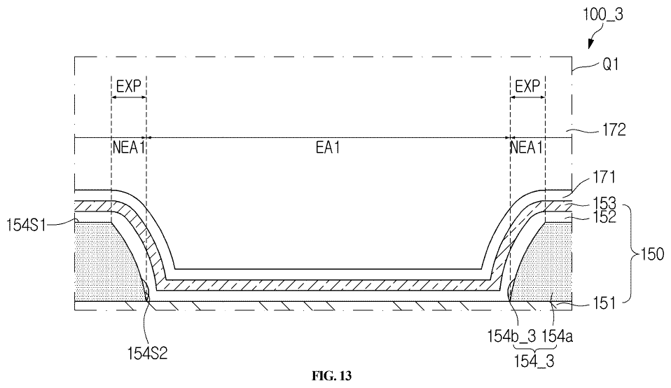

FIG. 13 is a cross-sectional view of a display device according to yet another embodiment.

Referring to FIG. 13, a display panel 100_3 of the display device according to the present embodiment differs from the display panel 100_2 according to FIG. 12 in that a second bank 154b_3 of a bank 154_3 may cover the lower end portion of the first bank 154a and may be disposed in an area corresponding to about ¼ of the length from one end (the end portion in contact with the first electrode 151).

Since the remaining parts have been described above in FIG. 12, the detailed descriptions thereof will be omitted.

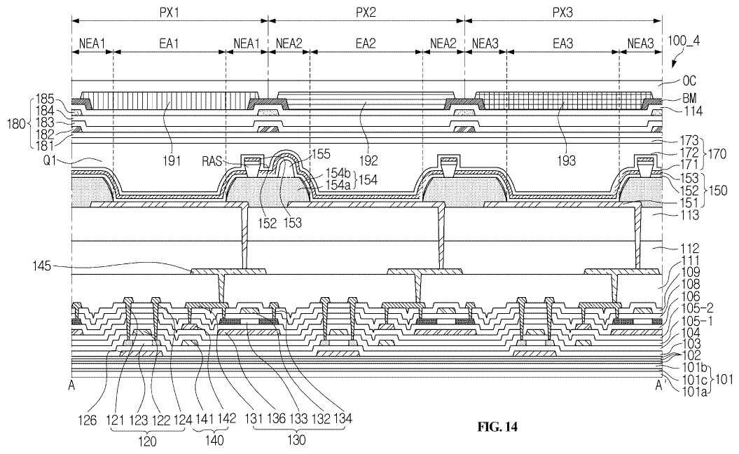

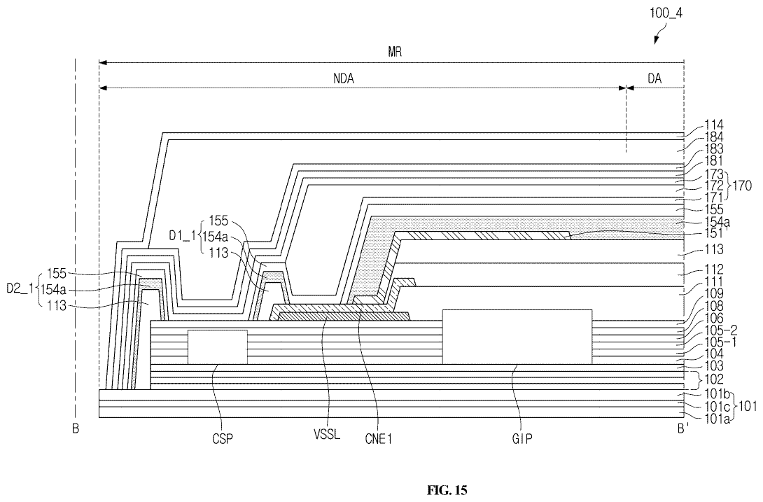

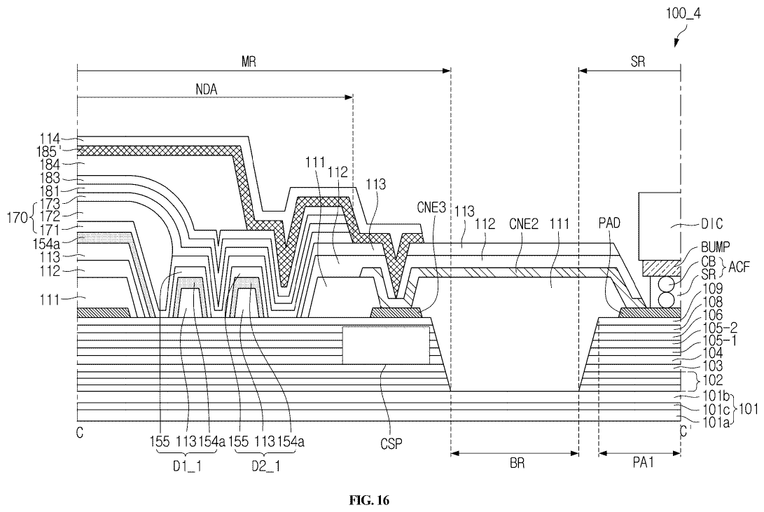

FIG. 14 is a cross-sectional view of a display device according to yet another embodiment. FIG. 15 is a cross-sectional view of the display device according to yet another embodiment. FIG. 16 is a cross-sectional view of the display device according to yet another embodiment.

Referring to FIGS. 14 to 16, a display panel 100_4 of the display device according to the present embodiment differs from the display panel 100 according to FIGS. 3, 7, and 8 in that it may further include a third protective layer 113 on the second protective layer 112.

More specifically, the display panel 100_4 according to the present embodiment may further include the third protective layer 113 between the second protective layer 112 and the first electrode 151. A material of the third protective layer 113 may include at least one of materials exemplified as the material of the second protective layer 112, but the embodiments of the present specification are not limited thereto.

As illustrated in FIGS. 15 and 16, each of a first dam D1_1 and a second dam D2_1 may include the third protective layer 113 as a first layer and may not include the second protective layer 112, but the embodiments of the present specification are not limited thereto.

Since the remaining parts have been described above in FIGS. 3, 7, and 8, the detailed descriptions thereof will be omitted below.

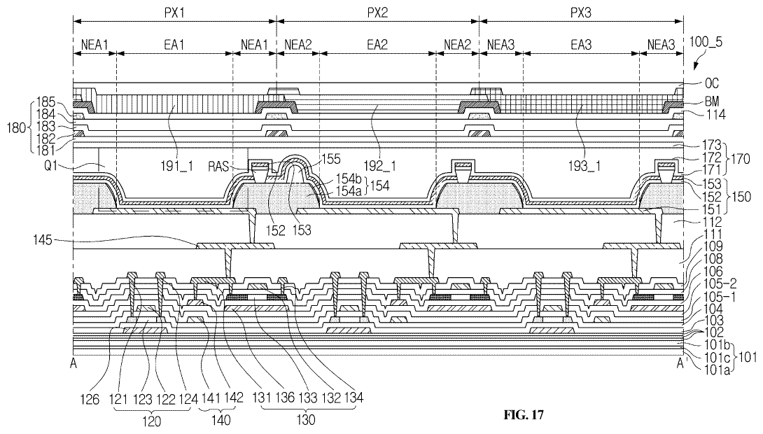

FIG. 17 is a cross-sectional view of a display device according to yet another embodiment.

Referring to FIG. 17, color filters 191_1, 192_1, and 193_1 of a display panel 100_5 of the display device according to the present embodiment differ from the display panel 100 according to FIG. 3 in that they may overlap each other in the non-light-emitting areas NEA1, NEA2, and NEA3.

FIG. 17 illustrates that a second color filter 192_1 is located at the top, a first color filter 191_1 is located under the second color filter 192_1, and lastly, a third color filter 193_1 is located at the bottom in each non-light-emitting area NEA1, NEA2, or NEA3, but the stacking order of the color filter 191_1, 192_1, and 193_1 in the non-light-emitting areas NEA1, NEA2, and NEA3 may vary according to a process order.

Since the remaining parts have been described above in FIG. 3, the detailed descriptions thereof will be omitted.

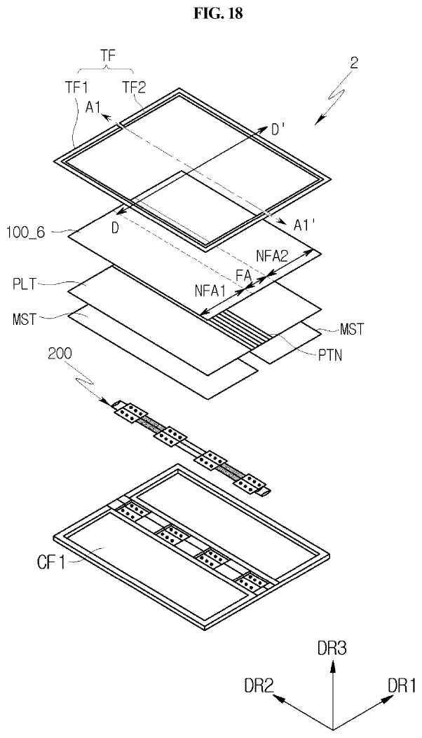

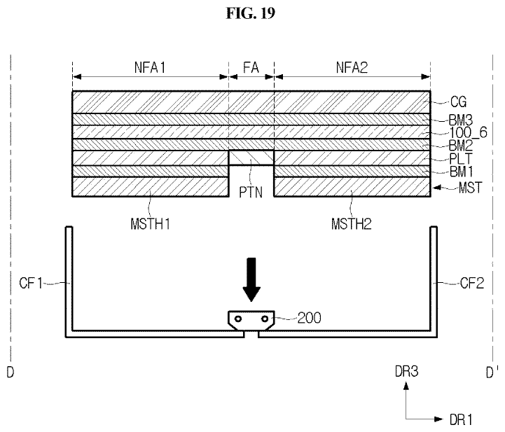

FIG. 18 is a perspective view of a display device according to yet another embodiment. FIG. 19 is a cross-sectional view along line D-D′ in FIG. 18 according to one embodiment.

Referring to FIGS. 18 and 19, a display device 2 according to the present embodiment differs from the display device 1 according to FIG. 1 in that it is a foldable display device.

In the present specification, a folding axis A1 along which the display device 2 is folded may be the same as the second direction DR2.

A top frame TF is disposed at the top of the display device 2. With respect to the folding axis A1, the top frame TF includes a first top frame TF1 disposed at one side and a second top frame TF2 disposed at the other side. The top frame TF may be disposed to cover an edge of the display panel 100_6. The top frame TF may protect the display panel 100_6 from an external impact. The top frame TF may form a bezel of the display device 2.

The cover layer CG may be disposed under the top frame TF. The cover layer CG may be disposed above the display panel 100_6.

The cover layer CG may be disposed above the display panel 100_6 to protect members disposed under the cover layer CG from the outside.

A panel assembly is disposed under the cover layer CG. The panel assembly includes the display panel 100_6 and a plate PLT. The display panel 100_6 may be substantially the same as one of the display panels 100, 100_1, 100_2, 100_3, 100_4, and 100_5.

The plate PLT may be disposed under the display panel 100_6 and may include various plates for supporting the display panel 100_6. For example, one or more plates may include a back plate for supporting the display panel 100_6, a top plate disposed under the back plate and formed of a stainless steel (SUS) material, a bottom plate disposed under the top plate, having a pattern formed on a folding portion, and formed of a SUS material, a heat-dissipation sheet that performs a heat-dissipation function, a middle plate for covering a non-planarized flat surface caused by various components of a hinge assembly, etc.

A slit pattern PTN may be formed in the plate PLT. The slit pattern PTN may be formed at a location corresponding to a folding area FA of the display panel 100_6. The slit pattern PTN may be a slit-shaped etched portion formed in the plate PLT. For example, the plate PLT may be formed of a metal, such as a SUS material, but the strong nature of the metal may cause problems in folding or unfolding the plate PLT. The slit pattern PTN may supplement the flexibility of the plate PLT.

A middle plate MST is disposed under the panel assembly. The middle plate MST supports components disposed upward. In addition, a hinge assembly 200 and a cover frame CF are disposed downward from the middle plate MST, and their upper surfaces may be uneven. The middle plate MST may flatten a non-planarized lower surface. The middle plate MST may be formed of a material, such as plastic, polyimide, or metal, to increase the rigidity of the display device 2. For example, the middle plate MST may include aluminum or SUS, but is not limited thereto.

The middle plate MST may include a first middle plate portion MSTH1 disposed in a first unfolding area NFA1, and a second middle plate portion MSTH2 disposed in a second unfolding area NFA2.

The hinge assembly 200 is disposed under the panel assembly. The hinge assembly 200 is disposed under the folding area FA. The hinge assembly 200 may have a shape extending along the folding axis A1. The hinge assembly 200 may perform a folding motion in which one side and the other side rotate about the folding axis A1.

The cover frame CF is disposed under the hinge assembly 200. An accommodation groove in which a part of the hinge assembly 200 may be seated may be formed in an upper surface of the cover frame CF. With respect to the folding axis A1, the cover frame CF includes a first cover frame CF1 disposed at one side and a second cover frame CF2 disposed at the other side. The cover frame CF may be a housing for defining the side and rear surfaces of the display device 2. The cover frame CF may protect the display device 2 from an external impact. The cover frame CF may be coupled to the hinge assembly 200. Folding and unfolding of the display device 2 may be implemented according to the rotation of the cover frames CF1 and CF2.

Coupling members BM1, BM2, and BM3 for coupling the adjacent members MST, PLT, PNL, and CG may be further disposed between the adjacent members. In each of the unfolding areas NFA1 and NFA2, a first coupling member BM1 may couple the middle plate portions MSTH1 and MSTH2 to the plate PLT disposed above the middle plate portions MSTH1 and MSTH2, a second coupling member BM2 may couple the plates PLT and PTN to the display panel 100_6 disposed above the plates PLT and PTN, and a third coupling member BM3 may couple the display panel 100_6 to the cover layer CG.

The plate PLT and the middle plate MST that are coupled may be seated on the cover frames CF1 and CF2. The display device 2 may perform folding and unfolding operations by the hinge assembly 200 disposed on the cover frames CF1 and CF2.

Since the display panel 100_6 has been described above, the detailed descriptions thereof will be omitted below.

A display device according to various embodiments of the present specification may be described as follows.

According to embodiments of the present disclosure, there is provided a display device including a substrate including a display area including a plurality of sub-pixels and a non-display area surrounding the display area, a first electrode disposed in each of the sub-pixels on the substrate, a first bank disposed on the first electrode, located at a boundary between adjacent sub-pixels, and including an upper surface and side surfaces, and a second bank that is disposed on the side surfaces of the first bank and exposes at least a part of the upper surface of the first bank, in which the first bank includes a black-based material.

In the display device according to various embodiments of the present specification, an optical density of the first bank may be greater than an optical density of the second bank.

In the display device according to various embodiments of the present specification, the first bank may be a black bank, and the second bank may be a transparent bank.

In the display device according to various embodiments of the present specification, the second bank may come into contact with the first bank.

In the display device according to various embodiments of the present specification, the second bank may completely cover the side surfaces of the first bank.

In the display device according to various embodiments of the present specification, the second bank may partially cover the upper surface of the first bank.

In the display device according to various embodiments of the present specification, the second bank may cover a lower end portion of the side surface of the first bank and expose an upper end portion of the side surface of the first bank.

In the display device according to various embodiments of the present specification, a thickness of the second bank may range from ⅙ to ⅔ times a thickness of the first bank.

The display device according to various embodiments of the present specification may further include a first transistor between the substrate and the first electrode, and a second transistor between the first transistor and the first electrode.

In the display device according to the embodiments of the present specification, a semiconductor layer of the first transistor may include a polysilicon, and a semiconductor layer of the second transistor may include an oxide.

The display device according to various embodiments of the present specification may further include a first protective layer between the second transistor and the first electrode, a connection electrode between the first protective layer and the first electrode, and a second protective layer between the connection electrode and the first electrode.

In the display device according to various embodiments of the present specification, the plurality of sub-pixels may include a first sub-pixel, a second sub-pixel, and a third sub-pixel, the organic layer on the first electrode may be disposed across the first sub-pixel to the third sub-pixel, and the organic layer may include a first light-emitting layer on the first sub-pixel, a second light-emitting layer on the second sub-pixel, and a third light-emitting layer on the third sub-pixel.

In the display device according to the embodiments of the present specification, in each sub-pixel, each of the first light-emitting layer, the second light-emitting layer, and the third light-emitting layer may be stacked in two or more layers.

The display device according to various embodiments of the present specification may further include an organic layer on the first electrode, a second electrode on the organic layer, and a black matrix located at a boundary between adjacent sub-pixels on the second electrode, in which a width of the black matrix may be smaller than a width of the first bank, and an end of the black matrix may be closer to the boundary between the adjacent sub-pixels than an end of the bank.

According to various embodiments of the present specification, there is provided a display device including a substrate including a display area including a plurality of sub-pixels and a non-display area surrounding the display area, a first electrode disposed in each of the sub-pixels on the substrate, a first bank disposed on the first electrode, located at a boundary between adjacent sub-pixels, and including an upper surface and side surfaces, and a second bank that is disposed on the side surfaces of the first bank and exposes at least a part of the upper surface of the first bank, in which the sub-pixel includes a non-light-emitting area corresponding to the first bank, and a light-emitting area exposed by the first bank, and the non-light-emitting area includes an extra light extraction area corresponding to the second bank.

In the display device according to various embodiments of the present specification, an optical density of the first bank may be greater than an optical density of the second bank.

In the display device according to various embodiments of the present specification, the first bank may be a black bank, and the second bank may be a transparent bank.

In the display device according to various embodiments of the present specification, the second bank may completely cover the side surface of the first bank.

In the display device according to various embodiments of the present specification, the second bank may partially cover the upper surface of the first bank.

In the display device according to various embodiments of the present specification, the second bank may cover a lower end portion of the side surface of the first bank and expose an upper end portion of the side surface of the first bank.

According to the embodiments of the present specification, by omitting the polarizing unit, the display device can have improved flexibility and can be applied to a foldable product in which a display area is folded.

According to the embodiments of the present specification, it is possible to improve external light reflection by arranging the color filter and the first bank including the black-based material.

According to the embodiments of the present specification, since the second bank exposes a part of the upper surface of the first bank, it is possible to improve external light reflection.

According to the embodiments of the present specification, since the second bank covers a part of the side surface of the first bank, it is possible to improve light extraction.

According to the embodiments of the present specification, since the second bank covers some or all of the side surface of the first bank, it is possible to improve light extraction and implement low power.

However, effects obtainable from the present specification are not limited to the above-described effects, and other effects that are not mentioned will be able to be clearly understood by those skilled in the art to which the present specification pertains based on the following description.

Although the embodiments of the present disclosure have been described above with reference to the accompanying drawings, those skilled in the art to which the present disclosure pertains will be able to understand that the above-described technical configuration of the present disclosure can be carried out in other specific forms without changing the technical spirit or essential features thereof. Accordingly, it should be understood that the above-described embodiments are illustrative and not restrictive in all respects. In addition, the scope of the present disclosure is described by the claims to be described below rather than the detailed description. In addition, the meaning and scope of the claims and all changed or modified forms derived from the equivalent concept should be construed as being included in the scope of the present disclosure.

### DESCRIPTION OF REFERENCE NUMERALS

1, 2: display device
100, 100_1, 100_2, 100_3, 100_4, 100_5, 100_6: display panel
D1, D2: dam

What is claimed is:

1. A display device comprising:
a substrate including a display area including a plurality of sub-pixels and a non-display area around the display area;
a first electrode in each of the plurality of sub-pixels on the substrate;
a first bank on the first electrode, the first bank located at a boundary between adjacent sub-pixels from the plurality of sub-pixels and including an upper surface and side surfaces; and
a second bank on the side surfaces of the first bank, the second bank exposing at least a part of the upper surface of the first bank,
wherein the first bank includes a black-based material.

2. The display device of claim 1, wherein an optical density of the first bank is greater than an optical density of the second bank.

3. The display device of claim 2, wherein the first bank is a black bank and the second bank is a transparent bank.

4. The display device of claim 1, wherein the second bank is in direct contact with the first bank.

5. The display device of claim 1, wherein the second bank completely covers the side surfaces of the first bank.

6. The display device of claim 5, wherein the second bank partially covers the upper surface of the first bank.

7. The display device of claim 1, wherein the second bank covers a lower end portion of the side surfaces and exposes an upper end portion of the side surfaces of the first bank.

8. The display device of claim 1, wherein a thickness of the second bank ranges from ⅙ to ⅔ times a thickness of the first bank.

9. The display device of claim 1, further comprising:
a first transistor between the substrate and the first electrode; and
a second transistor between the first transistor and the first electrode.

10. The display device of claim 9, wherein a semiconductor layer of the first transistor includes polysilicon and a semiconductor layer of the second transistor includes an oxide.

11. The display device of claim 9, further comprising:
a first protective layer between the second transistor and the first electrode;
a connection electrode between the first protective layer and the first electrode; and
a second protective layer between the connection electrode and the first electrode.

12. The display device of claim 1, wherein the plurality of sub-pixels include a first sub-pixel, a second sub-pixel, and a third sub-pixel, an organic layer on the first electrode is across the first sub-pixel to the third sub-pixel, and the organic layer includes a first light-emitting layer on the first sub-pixel, a second light-emitting layer on the second sub-pixel, and a third light-emitting layer on the third sub-pixel.

13. The display device of claim 12, wherein, in each of the plurality of sub-pixels, each of the first light-emitting layer, the second light-emitting layer, and the third light-emitting layer is stacked in two or more layers.

14. The display device of claim 1, further comprising:
an organic layer on the first electrode;
a second electrode on the organic layer; and
a black matrix located at a boundary between adjacent sub-pixels from the plurality of sub-pixels on the second electrode,
wherein a width of the black matrix is smaller than a width of the first bank, and an end of the black matrix is closer to the boundary between the adjacent sub-pixels than an end of the first bank.

15. A display device comprising:
a substrate including a display area including a plurality of sub-pixels and a non-display area around the display area;
a first electrode in each of the plurality of sub-pixels on the substrate;
a first bank on the first electrode, the first bank located at a boundary between adjacent sub-pixels from the plurality of sub-pixels and including an upper surface and side surfaces; and
a second bank on the side surfaces of the first bank, the second bank exposing at least a part of the upper surface of the first bank,
wherein a sub-pixel from the plurality of sub-pixels includes a non-light-emitting area corresponding to the first bank and a light-emitting area exposed by the first bank, and
the non-light-emitting area includes an extra light extraction area corresponding to the second bank.

16. The display device of claim 15, wherein an optical density of the first bank is greater than an optical density of the second bank.

17. The display device of claim 16, wherein the first bank is a black bank and the second bank is a transparent bank.

18. The display device of claim 15, wherein the second bank completely covers the side surfaces of the first bank.

19. The display device of claim 18, wherein the second bank partially covers the upper surface of the first bank.

20. The display device of claim 15, wherein the second bank covers a lower end portion of the side surfaces of the first bank and exposes an upper end portion of the side surfaces of the first bank.
